(19) United States
(12) Patent Application Publication
(10) Pub. No.: US 2008/0084955 A1
(43) Pub. Date: Apr. 10, 2008

(54) Fast-locked clock and data recovery circuit and the method thereof

(76) Inventors: Wei-Zen Chen, Hsinchu City (TW); Chin-Yuan Wei, Houlong Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/544,549

(22) Filed: Oct. 10, 2006

(51) Int. Cl. H03D 3/24

(52) U.S. Cl. 375/376

(57) ABSTRACT

The present invention discloses a fast-locked clock and data recovery circuit, which adopts a 2× oversampling technology and comprises: a multi phase-outputting phase-locked loop generating a plurality of phases θᵢ; a phase interpolator synthesizing the obtained phases θₙ and θₙ₊₂ into a sampling phase Φₙ based on the weighting coefficient k; a phase detector detects the phase lead or lag between the input data and the sampling phase and generates an up/down signal; and a phase search engine update the weighting coefficient and modulate the sampling phase according to the up/down correction signals. Further, the present invention proposes a data recovery circuit implementing a binary search method and a 2× oversampling method, whereby the time for clock locking can be greatly reduced. Furthermore, the present invention utilizes a multi-phase time-sharing parallel sampling technology to achieve high-speed operation and low power consumption.

### BACKGROUND OF THE INVENTION

1. Field of the Invention

The present invention relates to a data recovery circuit, particularly to a low-error rate and fast-locked clock and data recovery circuit.

2. Description of the Related Art

Generally, data recovery circuits may be categorized into two folds, one is based on phase-locked loop architecture, the other is based on oversampling technique. As shown in FIG. 1, the architecture of a phase-locked loop data recovery circuit comprises: a phase detector 1, a low pass filter 2, and a voltage-controlled oscillator 3. The phase detector 1 is used to make clock signals able to accurately sample input data and charge/discharge the low pass filter 2 and then change the phase of the voltage-controlled oscillator 3. Such a recovery circuit has the advantage of high-speed operation. However, under the operational condition of higher-noise input signals, it is difficult to achieve fast-locking and have low-jitter output signals at the same time.

As shown in FIG. 2, the architecture of an oversampling data recovery circuit comprises: a phase-locked loop 4 generating multiple sampling phases, a register 5, a phase detector 6, and parallel sampling circuits 7. The multiple sampling phases are generated from the phase-locked loop 4, and used to sample the input data in parallel. Meanwhile, each data is sampled by many times; next, the sampled results are stored in a register 5; After that, the phase detector 6 is used to detect which sampling phase is nearest to the middle point of the input data. When the loop is locked, the phase detector then is able to pick up the optimal sampling phase, and the input data sampled by the optimal sampling phase are sent to the output. Thereby, the bit error rate of the recovered data can be minimized. Although high speed data locking can be achieved by the oversampling technique incorporating digital circuits. However, it requires lots of digital circuits, which occupy a large chip area. Furthermore, as the oversampling circuit requires multiple sampling phases, they are difficult to be generated for a high frequency operation.

Accordingly, the present invention proposes a fast-locked clock and data recovery circuit to overcome the abovementioned problems.

### SUMMARY OF THE INVENTION

The primary objective of the present invention is to provide a fast-locked clock and data recovery circuit and the method thereof, wherein the optimal sampling phases are interpolated between two different phases signals, and the weighting coefficients for phase interpolations are stored in a recorder.

Another objective of the present invention is to provide a fast-locked clock and data recovery circuit and the method thereof, wherein the update of the weighting coefficient of the phase interpolator is controlled by a phase search engine, thus the locked time is greatly reduced, and high-speed and low power consumption can be achieved.

According to one aspect of the present invention, the fast-locked clock and data recovery circuit comprises: a phase-locked loop generating multiple output phases θₙ; a phase interpolator synthesizing the acquired phases θₙ and θₙ₊₂ into a sampling phase Φₙ according to the weighting coefficient k; a phase detector that samples the input data and generates a up/down correction signal; and a phase search engine that moderates the adjusting of the weighting coefficient k according to the up/down signals. The sampling phase then can be updated along with k to sample the input data by the optimal sampling phase.

The weighting coefficient k is updated through binary search approach according to the output of the phase detector during the process of phase acquisition. The phase search engine can be implemented by different approaches. Followings are two of the implementation examples:

Approach I: The phase search engine comprises a recorder and a counter. After the phase detector outputs an up/down correction signal, the counter then adds/or subtracts the value stored in the recorder according to the up/down signal; after that, the value stored in the recorder will be reduced by half, and the updating process will repeat again when the phase detector outputs a new up/down correction signal. If no up/down signal is generated, the counter remains at its current value. If the value stored in the recorder has been reduced to its minimal value β, β>0. The value stored in the recorder will be remained and unchanged.
Approach II: The phase search engine comprises a first recorder and a second recorder; the first recorder records the execution times of binary search (E), and the second recorder is based on a thermal meter code that represents the weighting coefficient k. If the full scale of the weighting coefficient is represented by W. When the phase detector outputs an up/down correction signal to the phase search engine, the first recorder will be increased by one, and the contents of the second recorder will be shift left or right according to the up/down signal to accomplish adds or subtracts

$$\frac{α W}{{2}^{E}} .$$

### Here α is a constant, and 0≦α≦1. If the value stored in the recorder has been increased to its maximum value ?, ?>0. The value stored in the recorder will be remained and unchanged.

To enable the objectives, technical contents, characteristics and accomplishments of the present invention to be easily understood, the preferred embodiments of the present invention are to be described in detail in cooperation with the attached drawings below.

### BRIEF DESCRIPTION OF THE DRAWINGS

FIG. 1 is a diagram schematically showing the architecture of a conventional phase-locked loop data recovery circuit;

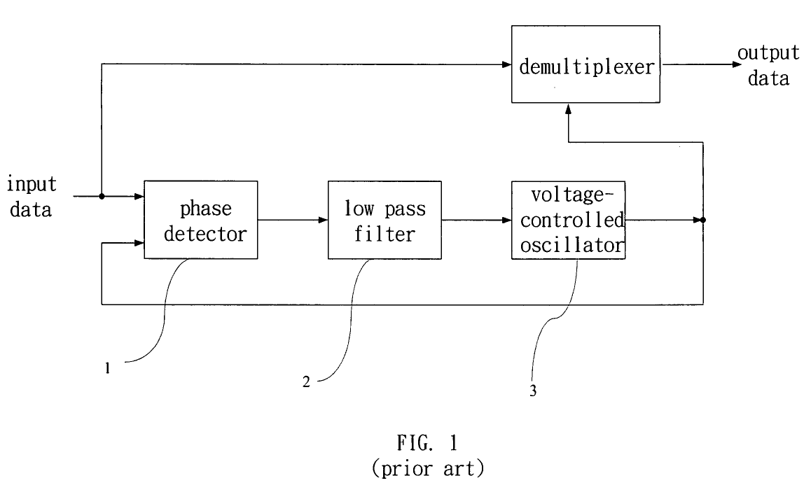

FIG. 2 is a diagram schematically showing the architecture of a conventional oversampling data recovery circuit;

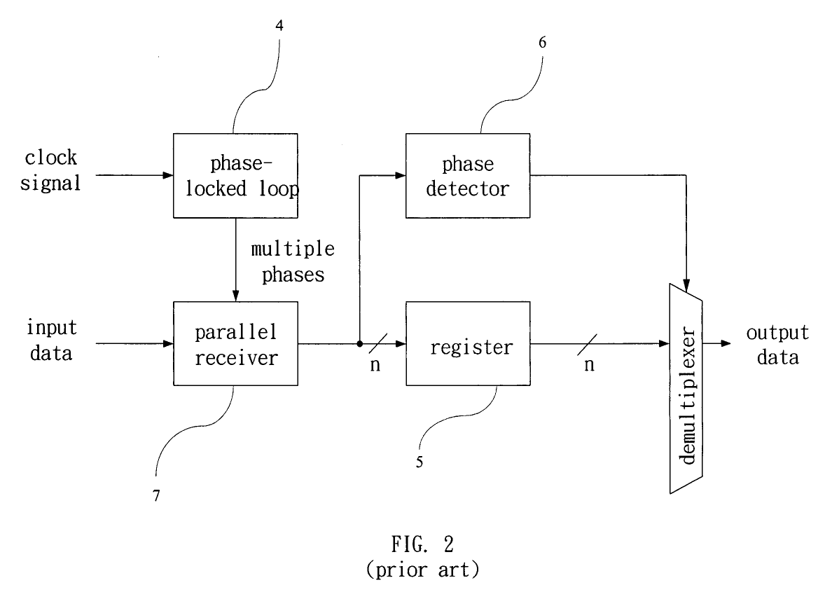

FIG. 3 is a diagram schematically showing the architecture of the fast-locked clock and data recovery circuit according to the present invention;

FIG. 4 is a diagram schematically showing the method of generating the sampling phases according to the present invention;

FIG. 5 is a diagram showing the circuit schematic of a phase detector example;

FIG. 6 is an example of the phase search engine;

FIG. 7 is an example of the phase search engine.

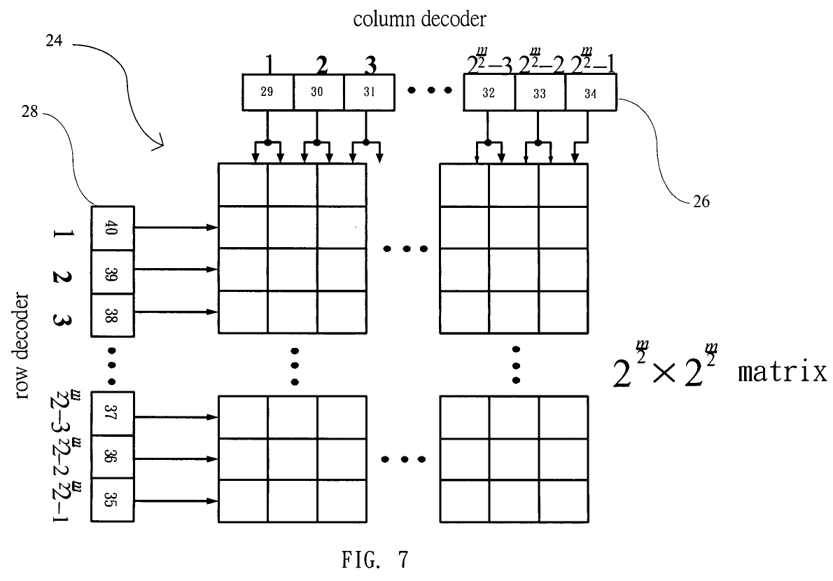

### DETAILED DESCRIPTION OF THE INVENTION

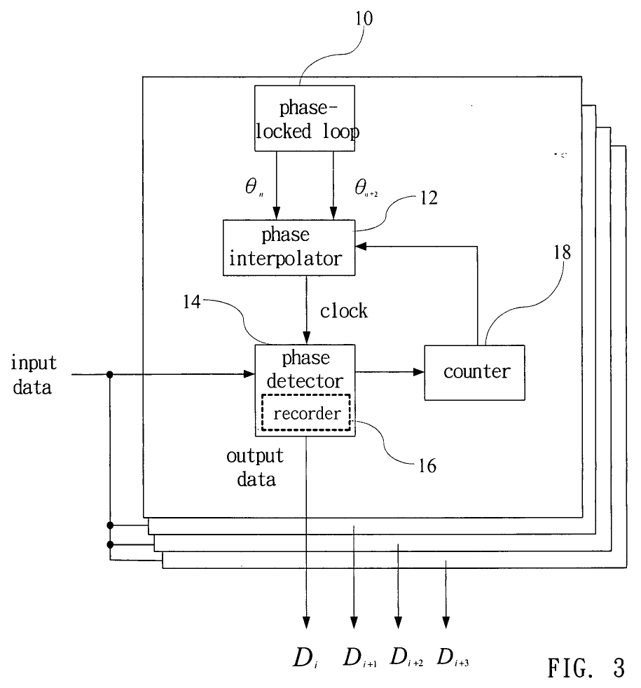

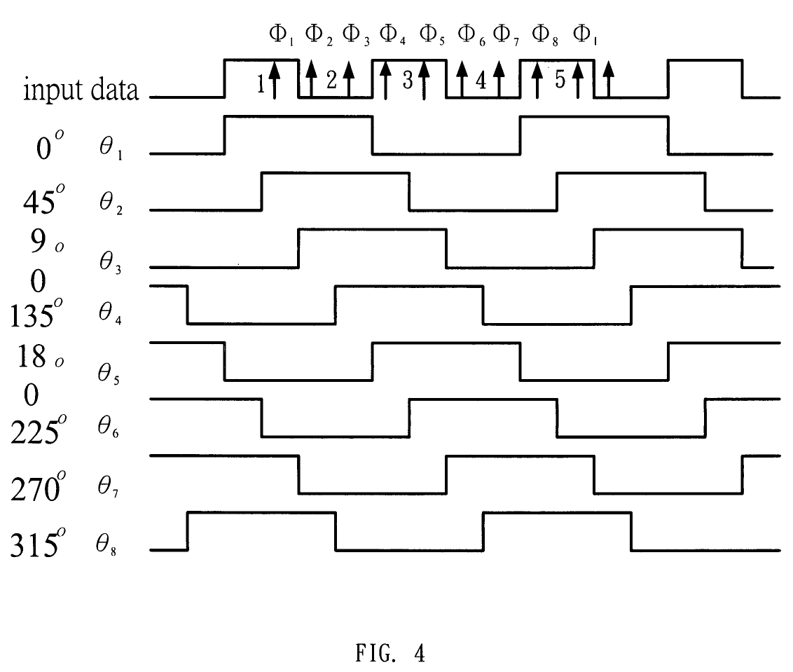

The present invention pertains to a fast-locked clock and data recovery circuit, which is used to search the optimal sampling phase, and then sample the input data by the optimal sampling phase. As shown in FIG. 3, the fast-locked clock and data recovery circuit of the present invention comprises a phase-locked loop 10 that generates multiple output phases θᵢ, i=1 to m. The operational frequency of the phase-locked loop 10 is 1/b times the input data rate, and m=2×b. For example, in this embodiment, the operation frequency of the phase-locked loop 10 is ¼ times the input data rate, and the phase-locked loop 10 generates eight uniformly distributed output phases. As shown in FIG. 4, among those eight phases, each two phases are input to a phase interpolator 12 and synthesized into a new phase, and there are altogether eight new phases synthesized and uniformly distributed. For example, the sampling phases Φₙ is interpolated between θₙ and θₙ₊₂, wherein Φₙ=θₙ×k+θₙ₊₂×(1−k), and k is a weighting coefficient.

A phase detector 14 detects the phase lead or lag between the sampling phase Φₙ (clock edge) and the input data, and generates a up/down signal accordingly. The phase search engine is exerted to moderate the update of the weighting coefficient k according to the up/down signal.

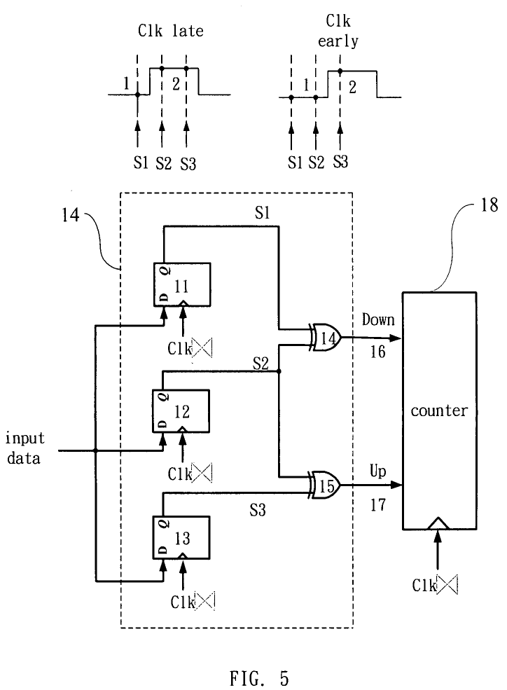

FIG. 5 shows an example of the phase detector. If the sampled data—S1 and S2—are different, the clock edge is recognized to be “early”. If S1 and S2 are identical, the clk edge is recognized to be “late”. In order to obtain the optimal sampling phase, when Clk is late, the phase detector 14 will output a “up” signal to the phase search engine to modulate the weighting coefficient of the interpolator and shift the interpolated phase toward θₙ; when Clk is early, the phase detector 14 will output an “down” signal to the phase search engine to shift the interpolated phase toward θₙ₊₂.

Refer to FIG. 4. The first input data is sampled by phases Φ₁, Φ₂, and Φ₃, and the sampled results are denoted as S1, S2, and S3 respectively, wherein Φ₁ is interpolated between θ₁ and θ₃; Φ₂ is interpolated between θ₂ and θ₄; and Φ₃ is interpolated between θ₃ and θ₅. The second input data is sampled by Φ₃, Φ₄, and Φ₅. Similarly, the third and fourth input data are also 2× oversampled with the same method. Repeatedly, the fifth input data is again oversampled by phases Φ₁, Φ₂, and Φ₃, and the sixth input data is oversampled by phases Φ₃, Φ₄, and Φ₅. After each comparison, the phases Φ₁, Φ₂, Φ₃, Φ₄, Φ₅ . . . are corrected once again until the optimal sampling phase has been reached.

The data recovery circuit of the present invention has been clarified above. How the phase search engine utilizes the binary search method to search for a right weighting coefficient k is to be described below. The circuit implementations of the phase search engine are not limited to the following two approaches.

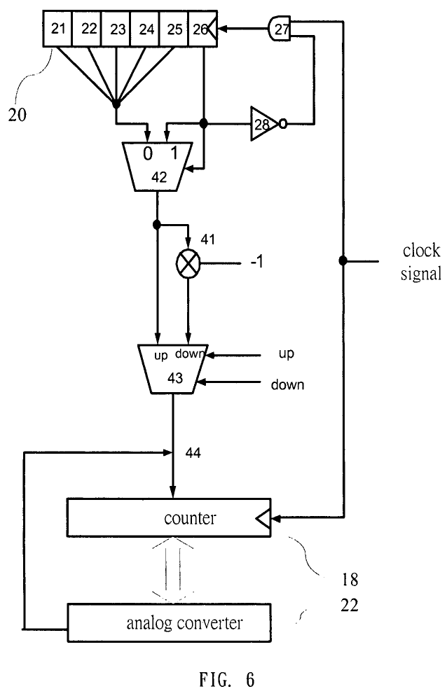

Approach I: As shown in FIG. 6, the phase search engine is realized with a recorder 20 and a counter 18. The phase detector 14 outputs an up/down signal to the phase search engine When an up correction signal is sent to the phase search engine, the counter 18 will accumulate the contents stored in the recorder 20. When a down signal is sent to the counter 18, the counter then subtracts the contents stored in the counter. After that, the contents of the recorder 20 will be reduced by half, and the contents of the counter represents the weighting coefficient k.
Approach II: As shown in FIGS. 9 and 10, the phase search engine is composed of a first recorder 30 and a second recorder 32. The first recorder 30 is an m bits registers used to record the number E of the executed binary searching actions, and the second recorder 32 is a L bit wide register that stores the weighting coefficient k in a thermal meter code. If the full scale of the weighting coefficient is represented by W. As the phase detector 14 outputs an up/down signal to the phase search engine. The contents of the second recorder 32 moves left or right according to the up/down signal to accomplish adds or subtracts

$$\frac{α W}{{2}^{E}} .$$

Here a is a constant, and 0≦α≦1. The abovementioned search steps are repeated until the optimal sampling phase is obtained. If the value stored in the recorder has been increased to its maximum value ?, ?>0. The value stored in the recorder will be remained and unchanged.

In summary, the present invention greatly reduces the time for clock and data recovery by means of the binary search method and 2× oversampling technology. Those embodiments described above are to exemplify the present invention to enable the persons skilled in the art to understand, make and use the present invention. However, it is not intended to limit the scope of the present invention. Any equivalent modification and variation according to the spirit of the present invention are to be also included within the scope of the claims of the present invention stated below.

What is claimed is:

1. A fast-locked clock and data recovery circuit, used to sample the input data, and comprising:
a phase-locked loop generating a plurality of phases θᵢ;
a phase interpolator acquiring said phases θₙ and θₙ₊₂ and synthesizing said sampling phase Φₙ by interpolating phases θₙ and θₙ₊₂;
a phase detector detecting phase lead or lag between the input data and the sampling phase and generates an up/down signal; and
a phase search engine firstly updating weighting coefficient k of the phase interpolator in a binary search manner according to said up/down signal.

2. The fast-locked clock and data recovery circuit according to claim 1, wherein relationship of said sampling phase Φₙ and said phases θₙ and θₙ₊₂ is expressed by
Φₙ=θₙ×k+θₙ₊₂×(1−k)

3. The fast-locked clock and data recovery circuit according to claim 2, wherein said phase search engine is composed of a counter and a recorder.

4. The fast-locked clock and data recovery circuit according to claim 3, wherein said counter may consist of extra digital low pass filters.

5. The fast-locked clock and data recovery circuit according to claim 3, wherein said recorder may be embedded in the said phase detector.

6. A fast-locked clock and data recovery method, comprising following steps:
updating a weighting coefficient k via a binary search engine;
outputting an up/down correction signal via a phase detector and then adding/or subtracting a value stored in a recorder via a counter according to said up/down correction signal;
reducing said value stored in said recorder by half and feeding back said value to said phase detector to update said up/down correction signal; and
repeating said steps above till stopping generating said up/down correction signal and said counter remaining at said current value.

7. The fast-locked clock and data recovery method according to claim 6, wherein said binary search engine comprising:
a first recorder recording execution times of binary search (E); and
a second recorder being based on a thermal meter code that represents said weighting coefficient k.

8. The fast-locked clock and data recovery method according to claim 7, wherein said first recorder increases by one and contents of said second recorder shift left or right according to said up/down correction signal to accomplish adds or subtracts
$$\frac{α W}{{2}^{E}}$$
wherein a is a constant and 0≦α≦1, and W represents full scale of said weighting coefficient k.
